(19) United States
(12) Patent Application Publication
(10) Pub. No.: US 2008/0017893 A1
(43) Pub. Date: Jan. 24, 2008

(54) Back-lit image sensor

(75) Inventors: Yvon Cazaux, Grenoble (FR); Francois Roy, Seyssins (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 11/824,287

(22) Filed: Jun. 29, 2007

(30) Foreign Application Priority Data
Jul. 5, 2006 (FR) FR06/52817

(51) Int. Cl. H01L 27/148; H01L 29/768

(52) U.S. Cl. 257/233

(57) ABSTRACT

An image sensor including a P-type doped layer of a semiconductor material including first and second opposite surfaces; and at least one photodiode formed in the layer on the side of the first surface and intended to be lit through the second surface. The dopant concentration in the layer increases from the first surface to the second surface.

### BACKGROUND OF THE INVENTION

1. Field of the Invention

The present invention relates to the field of image sensors intended to be used in cell phones, film cameras, camcorders, or digital photographic cameras. It more specifically relates to image sensors made in monolithic form based on semiconductor materials.

2. Discussion of the Related Art

FIG. 1 schematically illustrates an example of a circuit of a photosensitive cell of an array of photosensitive cells of an image sensor. With each photosensitive cell of the array are associated a precharge device and a read device. The precharge device is formed of an N-channel MOS transistor M1, interposed between a supply rail Vdd and a read node S. The gate of precharge transistor M1 is capable of receiving a precharge control signal RST. The read device is formed of the series connection of first and second N-channel MOS transistors M2, M3. The drain of first read transistor M2 is connected to supply rail Vdd. The source of second read transistor M3 is connected to an input terminal P of a processing circuit (not shown). The gate of first read transistor M2 is connected to read node S. The gate of second read transistor M3 is capable of receiving a read signal RD. The photosensitive cell comprises a charge storage diode D1 having its anode connected to a reference supply rail or circuit ground GND and its cathode directly connected to node S. The photosensitive cell comprises a photodiode D2 having its anode connected to reference supply rail GND and its cathode connected to node S via an N-channel charge transfer MOS transistor M4. The gate of transfer transistor M4 is capable of receiving a charge transfer control signal T. Generally, signals RD, RST, and T are provided by control circuits not shown in FIG. 1 and may be provided to all the photosensitive cells of the same row of the cell array. Diode D1 may be formed other than by a specific component. The function of storing the charges originating from photodiode D2 is then ensured by the apparent capacitance at read node S which is formed of the source capacitances of transistors M1 and M4, of the input capacitance of transistor M2, as well as of all the stray capacitances present at node S.

The operation of this circuit will now be described. A photodetection cycle starts with a precharge phase during which a reference voltage level is applied to diode D1. This precharge is performed by turning on precharge transistor M1. Once the precharge has been performed, precharge transistor M1 is off. The state at node S, that is, the real reference charge state of diode D1, is then read. The cycle carries on with a transfer to node S of the photogenerated charges, that is, those created and stored in the presence of a radiation, in photodiode D2. This transfer is performed by turning on transfer transistor M4. Once the transfer is over, transistor M4 is turned off, and photodiode D2 starts photogenerating and storing charges which will be subsequently transferred to node S. Simultaneously, at the end of the transfer, the new charge state of diode D2 is read. The output signal transmitted to terminal P then depends on the channel pinch of first read transistor M2, which is a direct function of the charge stored in the photodiode.

FIG. 2 schematically illustrates a photosensitive cell or pixel of a conventional image sensor intended to be lit on its front surface. Only photodiode D2 and transistor M4 are shown. In a P-substrate 1, a P-type region 2 more heavily doped than substrate 1 and an N-doped region 3 pinched between region 2 and substrate 1 which correspond to photodiode D2, which has a so-called pinched structure, are provided. The cell comprises a polysilicon portion 4 arranged on an insulating portion 6, spacers 7 being provided on either side of portions 4, 6. Polysilicon portion 4 corresponds to the gate of transistor M4 and insulating portion 6 corresponds to the gate oxide of transistor M4. An N-type region 8 corresponding to the read node of the photosensitive cell is provided in substrate 1. Metal interconnects, in the form of metal tracks and vias 9, are formed at the level of a stack of insulating layers 11 covering substrate 1 and are connected to the cell components. The cell also comprises a colored filter 12 covering insulating layer stack 11 on which a microlens 13 is arranged.

The light rays reaching microlens 13 are focused towards diode D2. However, incident light rays may be deviated or blocked by interconnects 9 and not reach photodiode D2. Further, the current tendency being to reduce the dimensions of photosensitive cells, the problem of the presence of metal interconnects 9 becomes all the greater. To overcome this problem, a lighting of photodiode D2 through the rear surface of substrate 1 has been devised.

FIGS. 3A to 3D schematically illustrate steps of an example of a conventional method for manufacturing a back-lit image sensor. FIG. 3A shows a heavily-doped P-type substrate 14 on which a P-type single-crystal silicon layer 15 less heavily doped than substrate 14 has been formed by epitaxy. Layer 15 comprises a front surface 16 and has, for example, a thickness of approximately 3 μm. FIG. 3B shows the structure obtained after having formed at the level of layer 15 the components associated with the pixels. In FIG. 3B, two adjacent pixels have been shown. The elements common to the pixel shown in FIG. 2 are designated with same references. To ensure the insulation between the two pixels, an insulation area 17, for example, made of silicon oxide, has been formed in layer 15. FIG. 3C shows the structure obtained after having formed interconnect levels 9 in the stack of insulating layers 11 covering layer 15 and after having glued on insulating layer stack 11 a second substrate 18 on which a silicon oxide layer 19 has been grown. FIG. 3D shows the structure obtained after having removed substrate 14, for example by a chem.-mech. polishing method, to define a rear surface 20 of layer 15 and after having formed on rear surface 20 color filter 21 and 22 and microlenses 23 and 24.

A disadvantage of the image sensor structure shown in FIG. 3D results from the electron diffusion in layer 15. Indeed, generally, incident photons cause the forming in layer 15 of electron/hole pairs, where the electrons forming in a portion of layer 15 associated with a photosensitive cell have to be captured by the photodiode of this cell. However, it can be observed that some electrons resulting from the absorption of photons in a portion of layer 15 associated with a photosensitive cell may be captured by the photodiodes of the adjacent photosensitive cells. This translates as an unwanted noise on the signals measured at the read nodes, the amplitude of which varies for each photosensitive cell. Such a phenomenon is due to the diffusion of electrons forming in a portion of layer 15 associated with a given photosensitive cell towards the photodiodes of the adjacent cells rather than towards the photodiode of the given photosensitive cell. The risk of diffusion of electrons towards adjacent cells is all the greater as this electron-forming site is remote from the photodiodes.

When the image sensor is lit on the front surface, this phenomenon is relatively insignificant. Indeed, the photons having their wavelengths corresponding to blue or green are mainly absorbed in the first two micrometers of substrate 1. Due to the focusing of the light rays by lens 13, the electrons resulting from the absorption of such photons form mainly in the vicinity of photodiode D2. The risk for some of these electrons to diffuse towards the adjacent photosensitive cells is thus low. Only the photons having a wavelength corresponding to red can be absorbed across a greater thickness of substrate 1. The risk for some of these electrons to diffuse towards adjacent cells is then greater, but the general number of electrons capable of diffusing towards adjacent cells remains low.

On the contrary, when the image sensor is lit on the rear surface, the risk of diffusion of electrons towards adjacent photosensitive cells is greater. Indeed, the electrons which have the greatest chances of diffusing towards adjacent photosensitive cells are those which form in the first two micrometers of layer 15 from rear surface 20. The number of these electrons is greater than for an image sensor lit from the front surface since they originate from the absorption of photons corresponding to colors blue, green, and red. The disturbance of the measured signals due to the diffusion of electrons towards the adjacent photosensitive cells is thus greater for an image sensor lit on the rear surface.

### SUMMARY OF THE INVENTION

A feature of the present invention provides a back-lit image sensor enabling decreasing, or even eliminating, the diffusion of electrons associated with a given pixel towards adjacent pixels.

Another feature of the present invention provides a method for manufacturing a back-lit image sensor enabling decreasing, or even eliminating, the diffusion of electrons associated with a given pixel towards adjacent pixels.

To achieve all or part of these objects, as well as others, an aspect of the present invention provides an image sensor comprising a P-type doped layer of a semiconductor material comprising first and second opposite surfaces; and at least one photodiode formed in the layer on the side of the first surface and intended to be lit through the second surface. The dopant concentration in the layer increases from the first surface to the second surface.

According to an example of embodiment of the present invention, the increase in the dopant concentration of the layer is substantially continuous.

According to an example of embodiment of the present invention, the dopant concentration of the layer increases stepwise.

According to an example of embodiment of the present invention, the dopant concentration of the layer is substantially constant across a given thickness from the first surface.

According to an example of embodiment of the present invention, the given thickness is 1 μm.

According to an example of embodiment of the present invention, the thickness of the layer ranges between 2 μm and 4 μm.

Another aspect of the present invention provides a device, especially a cell phone, a film camera, a camcorder, a digital microscope or a digital photographic camera, comprising an image sensor such as defined previously.

Another aspect of the present invention provides a method for manufacturing an image sensor comprising the steps of forming a layer of a P-type doped semiconductor material comprising first and second opposite surfaces, the dopant concentration of the layer increasing from the first surface to the second surface; and of forming in the layer at least one photodiode on the side of the first surface, intended to be lit through the second surface.

According to an example of embodiment of the present invention, the layer is formed by epitaxy.

According to an example of embodiment of the present invention, the layer is formed on an insulating layer covering a substrate, the substrate and at least a portion of said insulating layer being removed after forming of said photodiode.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1, previously described, shows an electric diagram of a photosensitive cell;

FIG. 2, previously described, shows a conventional front-lit image sensor;

FIGS. 3A to 3D, previously described, illustrate the successive steps of a conventional method for manufacturing a back-lit image sensor;

FIG. 4 shows an example of embodiment of a back-lit image sensor according to the present invention; and

FIG. 5 very schematically shows a cell phone comprising an image sensor according to the present invention.

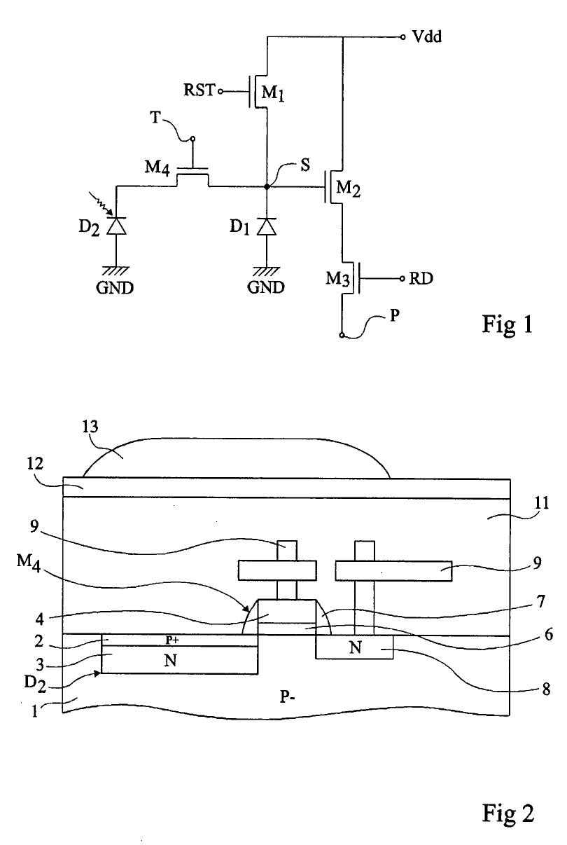

### DETAILED DESCRIPTION

For clarity, the same elements have been designated with the same reference numerals in the different drawings and, further, as usual in the representation of integrated circuits, the various drawings are not to scale.

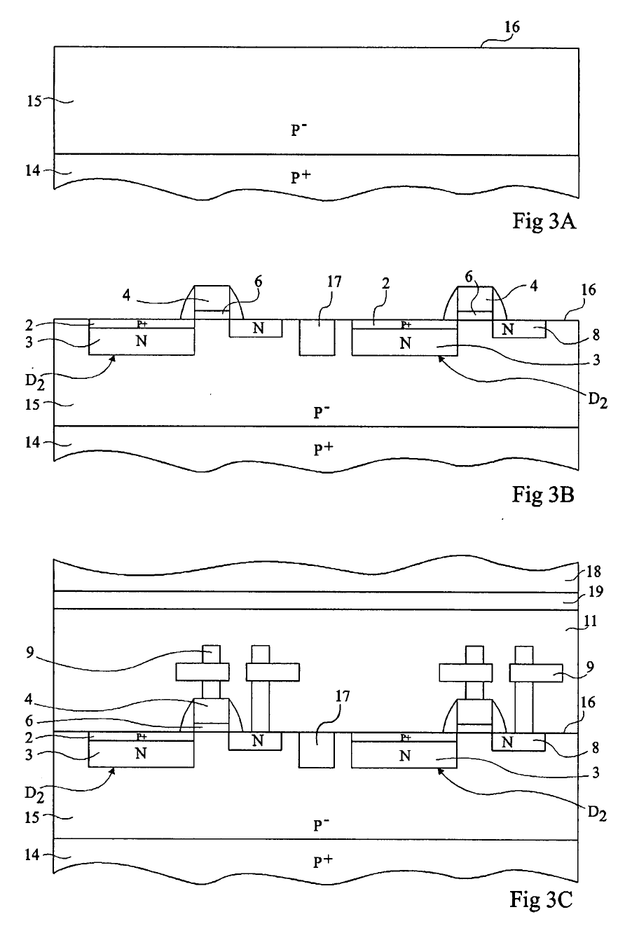

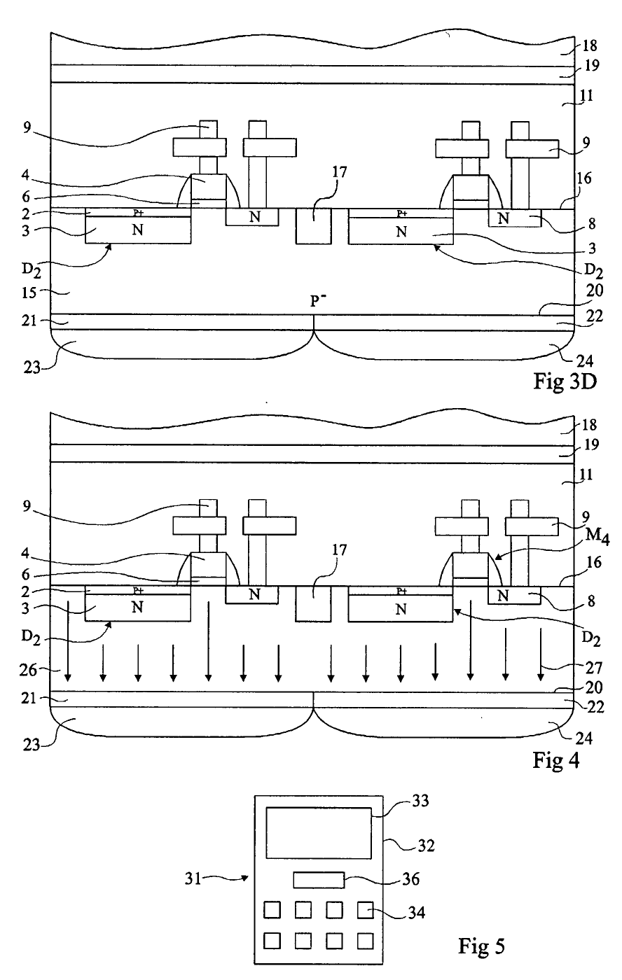

FIG. 4 is a drawing similar to FIG. 3D and shows an example of embodiment of an image sensor according to the present invention. As compared with the image sensor shown in FIG. 3D, lightly-doped P-type layer 15 has been replaced with a P-type doped silicon layer 26 having a dopant concentration increasing from front surface 16 of layer 26 to rear surface 20. As an example, the thickness of layer 26 may vary between 2 μm and 6 μm and the dopant concentration may vary from some 1014 atoms/cm3 close to front surface 16 to some 1017 atoms/cm3 close to rear surface 20. The dopant used is of type P, and, for example, may be boron. Arrows 27 illustrate the concentration gradient of dopants in layer 26. The manufacturing method of the present example of embodiment of the image sensor according to the present invention may be similar to the method previously described in relation with FIGS. 3A to 3D, layer 26 being formed by epitaxy on substrate 14. It is then provided, simultaneously to the epitaxial growth of layer 26, to form a P-type doping having its concentration increasing in the direction of arrows 27.

The dopant concentration gradient causes the forming of an electrostatic field in layer 26 oriented like the concentration gradient. This translates as the exerting of a force on the electrons forming in layer 26 oriented in the direction opposite to arrows 27. The electrons are thus led towards photodiode D2 associated to the portion of layer 26 of the pixel in which they have formed. The electrostatic field thus prevents the electrons from diffusing towards neighboring pixels.

The increase in the dopant concentration may be performed in continuous and regular fashion from front surface 16 to rear surface 20 of layer 26. As an example, the concentration increase may be rectilinear.

The dopant concentration in layer 26 may be constant across a given thickness from front surface 16 of layer 26, then increase towards rear surface 20. The given thickness may be on the order of 1 μm. This advantageously enables maintaining the dopant concentration constant at the level of the portions of layer 26 corresponding to the channel regions of the photosensitive cell transistors. Indeed, the electric adjustment of a MOS transistor to optimize its operation is very sensitive and is generally performed by considering that the silicon portion in which the transistor is formed has a constant dopant concentration. It can thus be advantageous to have a constant dopant concentration at the level of each transistor of the photosensitive cell to avoid modifying the working point of this transistor and especially the transistor channel forming conditions.

According to a variation of the present invention, insulation area 27 may correspond to a P-type area more heavily doped than layer 26. Insulation area 17 may be formed by one or several implantation steps. Insulation area 17 may extend from front surface 16 across the given thickness where the dopant concentration of layer 26 is constant.

According to an embodiment of the present invention, an SOI-type structure may be used for the forming of layer 26. The manufacturing method starts from the upper silicon layer of the SOI structure which acts as a seed layer. Silicon layer 26 with a variable dopant concentration may be formed by epitaxy on the seed layer.

According to a variation, the manufacturing method starts from the upper silicon layer of a SOI structure which acts again as a seed layer. Layer 26 with a variable dopant concentration may be formed by heavily doping the seed layer on the insulating layer of the SOI structure and by forming, by epitaxy with a constant dopant concentration, layer 26 on the seed layer. During the epitaxy, an exo-diffusion of the dopants occurs from the seed layer into layer 26.

FIG. 5 illustrates an example of the use of the image sensor according to the present invention. FIG. 5 very schematically shows a cell phone 31 comprising a package 32 at the level of which are arranged a screen 33 and a keyboard 34. The cell phone also comprises an image acquisition system 36 comprising an optical system directing the light rays towards an image sensor according to the present invention.

Of course, the present invention is likely to have various alterations, modifications, and improvements which will readily occur to those skilled in the art. In particular, the present invention also applies to a photosensitive cell for which several photodiodes are connected to a same read node. Further, although the present invention has been described for an image sensor cell in which the precharge device and the read device have a specific structure, the present invention also applies to a cell for which the precharge device or the read device have a different structure, for example, comprise a different number of MOS transistors.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An image sensor comprising:
a P-type doped layer of a semiconductor material comprising first and second opposite surfaces; and
at least one photodiode formed in said layer on the side of the first surface and intended to be lit through the second surface,
wherein the dopant concentration in said layer increases from the first surface to the second surface, the dopant concentration of said layer being substantially constant across a given thickness from the first surface.

2. The image sensor of claim 1, wherein the increase in the dopant concentration of said layer is substantially continuous.

3. The image sensor of claim 1, wherein the dopant concentration of said layer increases stepwise.

4. The image sensor of claim 1, comprising, in said layer, across the given thickness from the first surface, an insulation area of the P-type, more heavily doped than said layer and surrounding at least partially said photodiode.

5. The image sensor of claim 4, wherein the given thickness is 1 μm.

6. The image sensor of claim 1, wherein the thickness of said layer ranges between 2 μm and 4 μm.

7. A device, especially a cell phone, a film camera, a camcorder, a digital microscope or a digital photographic camera, comprising the image sensor of any of the foregoing claims.

8. A method for manufacturing an image sensor comprising:
forming a layer of a P-type doped semiconductor material comprising first and second opposite surfaces, the dopant concentration of said layer increasing from the first surface to the second surface and being substantially constant across a given thickness from the first surface; and
forming in said layer at least one photodiode on the side of the first surface, and intended to be lit through the second surface.

9. The method of claim 8, wherein said layer is formed by epitaxy.

10. The method of claim 8, wherein said layer is formed on an insulating layer covering a substrate, the substrate and at least a portion of said insulating layer being removed after forming of said photodiode.
